(19) United States
(12) Patent Application Publication
(10) Pub. No.: US 2026/0239609 A1
(43) Pub. Date: Aug. 13, 2026

(54) SEMICONDUCTOR DEVICE

(71) Applicant: Samsung Electronics Co., Ltd., Suwon-si (KR)

(72) Inventors: Jaeeuk Kim, Suwon-si (KR); Joon Han, Suwon-si (KR); Youngju Kwak, Suwon-si (KR); Sunhae Shin, Suwon-si (KR)

(73) Assignee: Samsung Electronics Co., Ltd., Suwon-si (KR)

(21) Appl. No.: 19/273,655

(22) Filed: Jul. 18, 2025

(30) Foreign Application Priority Data
Feb. 10, 2025 (KR) 10-2025-0016493

(51) Int. Cl. H10B 12/00

(52) U.S. Cl. CPC H10B 12/50

(57) ABSTRACT

A semiconductor device includes a substrate; a device isolation layer defining an active region on the substrate; a gate structure on the active region; a source/drain region having a P-type conductivity on at least one side of the gate structure; and a spacer covering a side surface of the gate structure, wherein the spacer includes a first spacer covering the side surface of the gate structure and having a first thickness, a second spacer covering an external side surface of the first spacer and having a second thickness greater than the first thickness, and a third spacer covering an external side surface of the second spacer and having a third thickness smaller than the first thickness, and wherein a level of lower surfaces of the first and second spacers is higher than a level of a lower surface of the third spacer.

### CROSS-REFERENCE TO RELATED APPLICATIONS

This present application claims priority to and the benefit under 35 U.S.C. § 119(a)-(d) of Korean Patent Application No. 10-2025-0016493 filed on Feb. 10, 2025, in the Korean Intellectual Property Office, the entire disclosure of which is incorporated herein by reference.

### BACKGROUND

Example embodiments of the present disclosure relate to a semiconductor device including a gate structure.

Semiconductor process technology has continuously developed to implement a high-performance and highly integrated semiconductor device. Particularly, a memory element such as a DRAM has been developed to reduce a size of components of an element to increase data storage capacity and to improve an operating speed. Recently, research has been actively conducted to improve carrier mobility using strained silicon technique in a P-type semiconductor device (pFETs). For example, silicon germanium (SiGe) may provide high hole mobility and may be used as an important material which may significantly improve performance of a P-type semiconductor device (pFETs) by forming a strained channel. For example, by introducing silicon germanium (SiGe) to a source/drain region, a lattice strain effect may be induced, such that carrier mobility may be improved and a current driving ability of the device may also be increased.

### SUMMARY

Example embodiments of the present disclosure relates to the issue that, when an epitaxial layer is applied to a P-type semiconductor device (pFET), an epitaxial silicon germanium layer formed in a source/drain region may diffuse into a lower portion of a gate spacer and may extend into a channel region. This diffusion may reduce structural precision of elements and may reduce a length of the channel region positioned between the source/drain regions, such that reliability of the semiconductor device may degrade. In particular, penetration of the source/drain region into a lower portion of a gate spacer has emerged as a critical issue which may lower reliability of the semiconductor device and may reduce predictability of device performance. Example embodiments of the present disclosure is to provide a semiconductor device having electrical properties and improved reliability by preventing the above issue when a source/drain region is formed.

According to example embodiments of the present disclosure, a semiconductor device includes a first source/drain region and a second source/drain region spaced apart from one another; a first active region between the first source/drain region and the second source/drain region; a second active region on the first active region; a gate structure on the second active region; and a first gate spacer on a first side surface of the gate structure and a second gate spacer on a second side surface of the gate structure, wherein each of the first and second gate spacers includes a first spacer on the second active region, and a second spacer covering an external side surface of the first spacer and covering a side surface of the second active region.

According to example embodiments of the present disclosure, a semiconductor device includes a source/drain region; a first active region disposed on one side of the source/drain region; a second active region on the first active region; a gate structure disposed on the second active region; and a gate spacer covering one side surface of the gate structure, and including a first spacer disposed on the second active region, and a second spacer extending along an external side surface of the first spacer and a side surface of the second active region, wherein the source/drain region has a recessed first surface, and includes a first epitaxial pattern in contact with a side surface of the first active region, a second epitaxial pattern disposed on the first surface and in contact with an external side surface of the second spacer, and a third epitaxial pattern disposed on the second epitaxial pattern and in contact with an external side surface of the second spacer.

According to example embodiments of the present disclosure, a semiconductor device, comprising: a substrate; a device isolation layer defining an active region on the substrate; a gate structure disposed on the active region; a source/drain region having a P-type conductivity on at least one side of the gate structure; and a spacer covering a side surface of the gate structure, wherein the spacer includes a first spacer covering the side surface of the gate structure and having a first thickness, a second spacer covering an external side surface of the first spacer and having a second thickness greater than the first thickness, and a third spacer covering an external side surface of the second spacer and having a third thickness smaller than the first thickness, a level of a lower surface of the first spacer is at a level higher than a level of a lower surface of the third spacer, and a level of a lower surface of the second spacer is at a level higher than a level of a lower surface of the third spacer.

According to example embodiments, a method of manufacturing a semiconductor device includes: providing a substrate, providing a device isolation layer defining an active region on the substrate, disposing a gate structure on the active region, disposing a source/drain region having a P-type conductivity on at least one side of the gate structure, disposing a spacer covering a side surface of the gate structure, wherein the spacer includes a first spacer covering the side surface of the gate structure and having a first thickness, a second spacer covering an external side surface of the first spacer and having a second thickness greater than the first thickness, and a third spacer covering an external side surface of the second spacer and having a third thickness smaller than the first thickness, a level of a lower surface of the first spacer is at a level higher than a level of a lower surface of the third spacer, and a level of a lower surface of the second spacer is at a level higher than a level of a lower surface of the third spacer.

### BRIEF DESCRIPTION OF THE DRAWINGS

The above and other aspects, features, and advantages of the present disclosure will be more clearly understood from the following detailed description, taken in combination with the accompanying drawings, in which:

FIG. 1 is a plan diagram illustrating a semiconductor device according to example embodiments of the present disclosure;

FIG. 2 is a cross-sectional diagram taken along line I-I′ in FIG. 1;

FIG. 3 is an enlarged diagram illustrating region ‘A’ in FIG. 2;

FIG. 4 is a cross-sectional diagram illustrating a semiconductor device according to example embodiments of the present disclosure;

FIG. 5 is an enlarged diagram illustrating region ‘A’ in FIG. 4;

FIG. 6A is a cross-sectional diagram illustrating a semiconductor device according to example embodiments of the present disclosure;

FIG. 6B is an enlarged diagram illustrating region ‘B’ in FIG. 6A;

FIG. 7 is a cross-sectional diagram illustrating a semiconductor device according to example embodiments of the present disclosure;

FIG. 8A is a plan diagram illustrating a semiconductor device according to example embodiments of the present disclosure;

FIG. 8B is a cross-sectional diagram taken along line I-I′ in FIG. 8A;

FIG. 8C is a cross-sectional diagram illustrating sections taken along lines II-II′ and III-III′ in FIG. 8A.

FIG. 9 is a perspective diagram illustrating a semiconductor device according to example embodiments of the present disclosure;

FIG. 10 is a process flowchart illustrating main processes of a method of manufacturing a semiconductor device according to example embodiments of the present disclosure;

FIGS. 11A to 11H are cross-sectional diagrams illustrating processes of manufacturing a semiconductor device according to example embodiments of the present disclosure; and

FIGS. 12A to 12D are cross-sectional diagrams illustrating processes of manufacturing a semiconductor device according to example embodiments of the present disclosure.

### DETAILED DESCRIPTION

Hereinafter, embodiments of the present disclosure will be described as below with reference to the accompanying drawings.

Unless otherwise indicated, in example embodiments, the terms such as “upper portion,” “upper surface,” “lower portion,” “lower surface,” “side surface,” or the like, are based on the drawings and may vary depending on the direction in which a component is disposed.

The terms “first,” “second,” and the like may be used to distinguish one element from the other, and may not limit a sequence and/or an importance, or others, in relation to the elements. In some cases, a first element may be referred to as a second element, and similarly, a second element may be referred to as a first element without departing from the scope of right of the example embodiments.

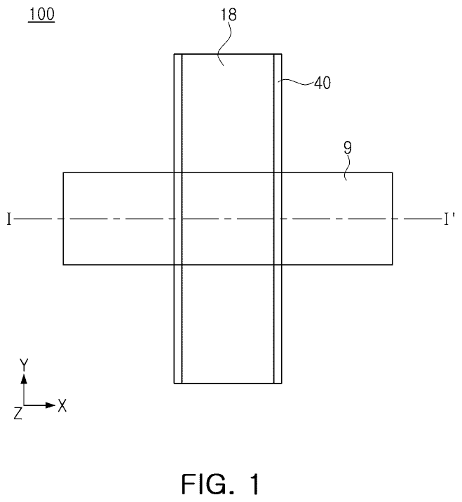

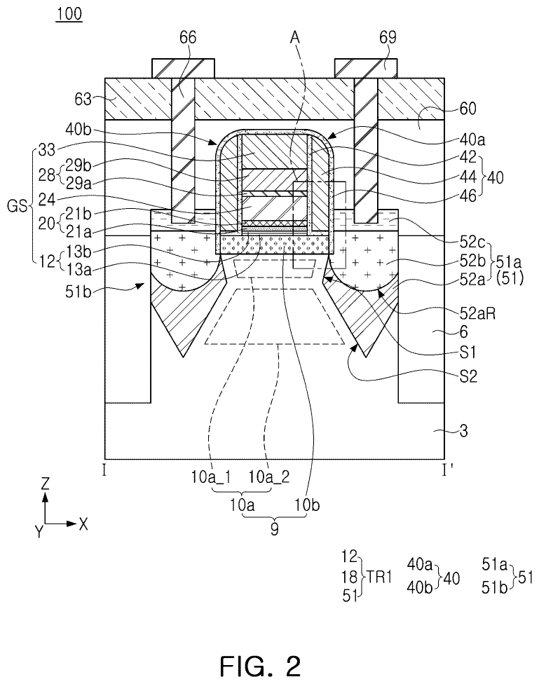

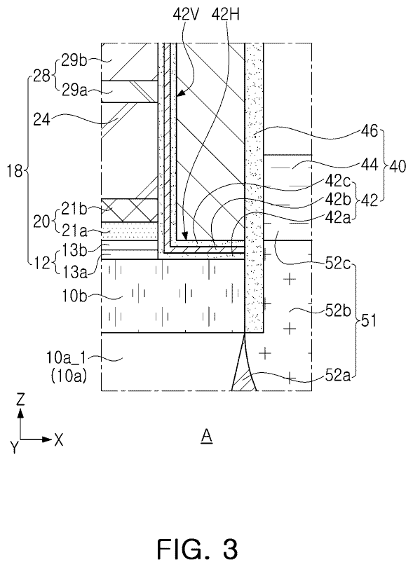

FIG. 1 is a plan diagram illustrating a semiconductor device according to example embodiments. FIG. 2 is a cross-sectional diagram taken along line I-I′ in FIG. 1. FIG. 3 is an enlarged diagram illustrating region ‘A’ in FIG. 2.

For ease of description, only a portion of components of the semiconductor device are illustrated in FIG. 1.

Referring to FIGS. 1 and 2, an active region 9 may extend in a first direction, for example, the X-direction, on the substrate 3. A gate structure GS may be disposed to intersect the active region 9 and to extend in a second direction, for example, the Y-direction. A channel region of the transistors may be formed in the active region 9 intersecting a gate electrode 18 of the gate structure GS.

Referring to FIG. 2, a semiconductor device 100 according to example embodiments may include a gate structure GS disposed on the active region 9, a source/drain region disposed on both sides of the gate structure GS, and a gate spacer on a side surface of the gate structure GS. The semiconductor device 100 may further include a substrate 3, an active region 9 disposed on the substrate 3, and a device isolation layer 6 defining the active region 9 on the substrate 3.

The substrate 3 may be a semiconductor substrate. For example, the substrate 3 may include a semiconductor material, such as a group IV semiconductor, a group III-V compound semiconductor, or a group II-VI compound semiconductor. For example, the group IV semiconductor may include silicon, germanium, or silicon-germanium. The substrate 3 may also be provided as a bulk semiconductor wafer, a semiconductor substrate including an epitaxial layer, a silicon on insulator (SOI) substrate, or a semiconductor on insulator (SeOI) substrate.

In example embodiments, an upper surface of the substrate 3 may include a {100} crystal plane. For example, an upper surface of the substrate 3 may be one of a (−1 0 0) plane, (0 1 0) plane, (0 −1 0) plane, (0 0 1) plane, or (0 0 −1) plane.

The device isolation layer 6 may define an active region 9 within the substrate 3. The device isolation layer 6 may be formed, for example, by a shallow trench isolation (STI) process. The device isolation layer 6 may expose an upper surface of the active region 9, and may also expose a portion of an upper portion. In some example embodiments, the device isolation layer 6 may have an upper surface curved to have a higher level toward the active region 9. The device isolation layer 6 may be formed of an insulating material. The device isolation layer 6 may be, for example, an oxide, a nitride, or a combination thereof.

The active region 9 may have a shape of protruding in a vertical direction from the substrate 3. Accordingly, the active region 9 may be formed of the same material as the substrate 3, for example, a semiconductor material. The active region 9 may or may not include a well region including impurities. For example, in the case of a P-type transistor (pFET), the well region may include n-type impurities such as phosphorus (P), arsenic (As), or antimony (Sb). The well region may be positioned at a predetermined depth from an upper surface of the active region 9, for example.

The active region 9 may be formed as a portion of the substrate 3, and may include an epitaxial layer grown from the substrate 3. However, the active region 9 may be partially recessed on both side surfaces of the gate structure GS, such that recess regions may be formed, and the source/drain regions 51 may be disposed in the recess regions.

The active region 9 may include a first active region 10a and a second active region 10b on the first active region 10a between the source/drain regions 51.

The first active region 10a may be disposed between the first source/drain region 51a and the second source/drain region 51b, and may be disposed on one side of each of the first and second source/drain regions 51a and 51b. A thickness of the first active region 10a may be greater than a thickness of the second active region 10b. The second active region 10b may be defined as a region including a region in which a channel working as a current passage between the source/drain regions 51 is formed. A thickness of the region in which the channel is formed within the active region may be relatively smaller than that of a region in which the channel is not formed. Accordingly, the thickness of the first active region 10a may be greater than the thickness of the second active region 10b.

The first active region 10a may include a first region 10a_1 of which a width may decrease in a direction away from the second active region 10b, and a second region 10a_2 of which a width increases in a direction away from the second active region 10b below the first region 10a_1. The first region 10a_1 may have a width decreasing toward the substrate 3, and the second region 10a_2 may have a width increasing toward the substrate 3. This may be a structure formed due to a difference in etching speed according to a crystal structure of a material forming the active region 9 in a recess process for forming the source/drain regions 51 in the active region 9.

The first region 10a_1 and the second region 10a_2 may be in contact with each of the first epitaxial pattern 52. In example embodiments, an upper surface of the substrate 3 and the active region 9 may include a {100} crystal plane. For example, an upper surface of the substrate 3 may be one of a (−1 0 0) plane, (0 1 0) plane, (0 −1 0) plane, (0 0 1) plane, or (0 0 −1) plane.

In example embodiments, the first region 10a_1 may have a first surface in contact with the first epitaxial pattern 52. In example embodiments, the first surfaces may include a {110} crystal plane. For example, the first surface may be one of (1 1 0) plane, (−1 1 0) plane, (1 −1 0) plane, (−1 −1 0) plane, (1 0 1) plane, (−1 0 1) plane, (1 0 −1) plane and (−1 0 −1) plane, (0 1 1) plane, (0 1 −1) plane, (0 1 −1) plane, or (0 −1 −1) plane.

The second region 10a_2 may have a second surface in contact with the first epitaxial pattern 52 below the first surface. In example embodiments, the first and second surfaces may include a {111} crystal plane. For example, the second inclined surface 152s may be one of a (1 1 1) plane, (1 1 −1) plane, (1 −1 1) plane, (1 −1 −1) plane, (−1 1 1) plane, (−1 1 −1) plane, (−1 −1 1) plane, or (−1 −1 −1) plane.

For example, when the crystal plane of the first surface close to the second active region 10b is formed as {110}, speed and efficiency of electron movement between the source/drain regions 51 and the second active region 10b may be increased due to the arrangement of the crystal structure as compared to the example in which {111} crystal plane is formed. Also, when the source/drain regions 51 include a silicon-germanium compound (SiGe) formed by an epitaxial growth method, structural mismatch between the epitaxial silicon-germanium compound (SiGe) and the strained silicon (Strained-Si) forming the second active region 10b may be reduced, thereby reducing defects between interfacial surfaces. Accordingly, electrical performance of the semiconductor device 100 and reliability of the elements may be improved.

The second active region 10b may be disposed on the first active region 10a. The second active region 10b may be positioned between the first active region 10a and the gate structure GS. A channel region of a transistor may be formed in the second active region 10b.

The source/drain regions 51, the gate dielectric pattern 12, and the gate electrode 18 may form a transistor TR1. In an example, the transistor TR1 may be configured as a PMOS transistor.

The source/drain regions 51 may be disposed in recess regions formed within the active region 9 adjacent to at least one side, for example, both sides, of the gate electrode 18. The source/drain regions 51 may include a first source/drain region 51a disposed on one side surface relative to the gate electrode 18 and a second source/drain region 51b spaced apart from the first source/drain region 51a.

Upper surfaces of the source/drain regions 51 may be positioned at a level the same as or higher than a level an upper surface of the second active region 10b of the active region 9, and the level may be varied in example embodiments. In example embodiments, side surfaces of the source/drain regions 51 may be curved with respect to the first active region 10a. However, the specific shape of the side surfaces of the source/drain regions 51 may be varied in example embodiments.

The source/drain regions 51 may include at least one of a semiconductor material, for example, silicon (Si) or germanium (Ge), and may further include dopants. For example, the source/drain regions 51 may include a silicon-germanium compound (SiGe), which may be silicon-germanium (SiGe) formed by an epitaxial growth method. Also, when the semiconductor device 100 is a pFET, the dopants may be at least one of boron (B), gallium (Ga), or indium (In). However, example embodiments thereof is not limited thereto.

For example, in the case of a P-type transistor (pFET), the first epitaxial pattern 52a and the second epitaxial pattern 52b may have different impurity concentrations or different Ge concentrations. The first epitaxial pattern 52a may include silicon-germanium (SiGe) doped with P-type impurities. For example, the P-type impurities may be at least one of boron (B), gallium (Ga), or indium (In). In some example embodiments, the first epitaxial pattern 52a may be a silicon-germanium (SiGe) compound doped with boron (B). In some example embodiments, the first epitaxial pattern 52a may have a first concentration of germanium (Ge), and the second epitaxial pattern 52b may have a second concentration of germanium (Ge) greater than the first concentration of germanium (Ge). For example, the first concentration of germanium (Ge) may be 0 at % to 20 at %, and the second concentration of germanium (Ge) may be 20 at % to 60 at %.

The third epitaxial pattern 52c may include silicon doped with P-type impurities. For example, the P-type impurities may be at least one of boron (B), gallium (Ga), or indium (In). In some example embodiments, the third epitaxial pattern 52c may be a silicon (Si) compound doped with boron (B). However, example embodiments thereof is not limited thereto.

By disposing the third epitaxial pattern 52c, contact resistance between the second epitaxial pattern 52b having a high concentration of germanium (Ge) and the contact structure 66 may be reduced. When the contact structure 66 and the second epitaxial pattern 52b formed of silicon-germanium (SiGe) are in direct contact with one another, an unstable interfacial surface may be formed, but as the contact structure 66 is in contact with the third epitaxial pattern 52c formed of a silicon (Si) compound, a stable interfacial surface may be provided. Accordingly, electrical properties of the semiconductor device may be improved and reliability of the elements may be improved.

Referring to FIG. 2, the source/drain regions 150 may include a first epitaxial pattern 52a, a second epitaxial pattern 52b, and a third epitaxial pattern 52c.

The first epitaxial pattern 52a may be disposed on an upper surface of the active region 9 and at least one side (e.g., both sides) of the gate spacer 40. The first epitaxial pattern 52a may be in contact with a side surface of the first active region 10a. Also, the first epitaxial pattern 52a may be disposed on a side surface of the first active region 10a and may be connected to the second active region 10b. For example, the first epitaxial pattern 52a may be connected to a lower surface of the second active region 10b disposed below the gate structure 160. The first epitaxial pattern 52a may be isolated from the gate electrode 18 by the gate spacer 40 and/or the outer side spacer 46. The first epitaxial pattern 52a may include an epitaxial layer. For example, the first epitaxial pattern 52a may be formed from the active region 9 by an epitaxial growth method.

The first epitaxial pattern 52a may include a first surface recessed in the upper surface. For example, as illustrated in FIG. 2, the first epitaxial pattern 52a may have a ‘U’ shape in a cross-sectional surface intersecting the second direction (e.g., Y-direction).

The second epitaxial pattern 52b may be disposed on the first epitaxial pattern 52a. A partial side surface of the second epitaxial pattern 52b may be in contact with an external side surface of the third spacer 46. The second epitaxial pattern 52b may overlap in the first direction (e.g., X-direction). The second epitaxial pattern 52b may be connected to the first epitaxial pattern 52a. As illustrated in FIG. 2, the second epitaxial pattern 52b may fill a space formed by a recessed surface of the first epitaxial pattern 52a. For example, a level of an upper surface of the second epitaxial pattern 52b may be higher than a level of an upper portion of the recessed surface on the first epitaxial pattern 52a with respect to a lower surface of the substrate 3. Accordingly, a contact area between the first epitaxial pattern 52a and the second epitaxial pattern 52b may be increased, such that contact resistance between the first epitaxial pattern 52a and the second epitaxial pattern 52b may be improved.

A width in the first direction (e.g., X-direction) of the second epitaxial pattern 52b may not be constant in the height direction (that is, third direction (e.g., Z-direction)). The second epitaxial pattern 52b may be formed on a recessed surface having a width in the first direction (e.g., X-direction) decreasing toward the substrate 3, such that a width in the first direction (e.g., X-direction) of the second epitaxial pattern 52b may also decrease toward the substrate 3.

The third epitaxial pattern 52c may be disposed on the second epitaxial pattern 52b. A partial side surface of the third epitaxial pattern 52c may be in contact with an external side surface of the third spacer 46. A lower surface of the third epitaxial pattern 52c may be connected to an upper surface of the second epitaxial pattern 52b.

The gate structure GS may be disposed on the second active region 10b. The gate structure GS may include a gate dielectric pattern 12 on the second active region 10b, a gate electrode 18 on the gate dielectric pattern 12, and a gate capping pattern 33 on the gate electrode 18.

The gate dielectric pattern 12 may be disposed on the active region 9 between the source/drain regions 51, and may be disposed on the second active region 10b positioned between the source/drain regions 51.

The gate dielectric pattern 12 may include a lower dielectric layer 13a and an upper dielectric layer 13b on the lower dielectric layer 13a. The lower dielectric layer 13a may include a silicon oxide or a silicon-based dielectric. The upper dielectric layer 13b may include a high-k dielectric having a dielectric constant greater than a dielectric constant of silicon oxide. For example, the upper dielectric layer 13b may include at least one of hafnium oxide (HfO), a hafnium-based oxide (Hf-based oxide), aluminum oxide (AlO), aluminum-based oxide (Al-based oxide), lanthanum oxide (LaO), lanthanum-based oxide (La-based oxide), magnesium oxide (MgO), or magnesium oxide (Mg-based oxide). Although not illustrated, in some example embodiments the lower dielectric layer 13a may have a thickness greater than that of the upper dielectric layer 13b. However, example embodiments thereof is not limited thereto.

The gate electrode 18 may include a lower conductive pattern 20 on the gate dielectric pattern 12, an intermediate conductive pattern 24 on the lower conductive pattern 20, and an upper conductive pattern 28 on the intermediate conductive pattern 24.

The lower conductive pattern 20 may be configured as a work function tuning layer. For example, the lower conductive pattern 20 may be configured as a PMOS work function tuning layer formed of a conductive material which may adjust or control a threshold voltage of the PMOS transistor.

The lower conductive pattern 20 may include at least one of TiN, TiAl, TiAlC, TiAlN, TaN, TaAlC or TaAlN. In the lower conductive pattern 20, by adjusting the amount of a metal element of at least one material of TiN, TiAl, TiAlC, TiAlN, TaN, TaAlC or TaAlN, the lower conductive pattern 20 may work as a PMOS work function tuning layer.

The lower conductive pattern 20 may include at least two conductive layers. For example, the lower conductive pattern 20 may include a first lower conductive layer 21a and a second lower conductive layer 21b on the first lower conductive layer 21a. The first lower conductive layer 21a may include a rare earth metal element (e.g., La), and the second lower conductive layer 21b may include at least one of TiN, TiAl, TiAlC, TiAlN, TaN, TaAlC or TaAlN.

The intermediate conductive pattern 24 may be formed of a material different from the material of the lower conductive pattern 20. For example, the intermediate conductive pattern 24 may include polysilicon. For example, the intermediate conductive pattern 24 may be formed of doped polysilicon. For example, the intermediate conductive pattern 24 may be formed of polysilicon having N-type conductivity.

In an example, when the transistor TR1 is configured as a PMOS transistor, the transistor TR1 may include the lower conductive pattern 20, which may be a PMOS work function tuning layer, such that the intermediate conductive pattern 24 may be formed of polysilicon having N-type conductivity instead of polysilicon having P-type conductivity. Accordingly, electrical properties of the gate electrode 18 may be improved without degrading performance of the transistor TR1.

The upper conductive pattern 28 may include a material different from a material of the lower conductive pattern 20 and a material of the intermediate conductive pattern 24. The upper conductive pattern 28 may include at least two conductive layers. For example, the upper conductive pattern 28 may include a first upper conductive layer 29a and a second upper conductive layer 29b on the first upper conductive layer 29a. The first upper conductive layer 29a may include a titanium silicon nitride (TiSiN) layer. The second upper conductive layer 29b may include a tungsten (W) layer.

The gate capping pattern 33 may include an insulating material, for example, silicon nitride. The gate capping pattern 33 may be disposed on the upper conductive pattern 28.

The gate spacer 40 may be disposed on both side surfaces of the gate structure GS on the second active region 10b. For example, the gate spacer 40 may include a first gate spacer on a first side surface of the gate structure GS and a second gate spacer on a second side surface positioned in an opposite direction to the first side surface of the gate structure GS. The gate spacer 40 may cover a side surface of the gate electrode 18 and a side surface of the gate capping pattern 33. Accordingly, the gate spacer 40 may insulate the source/drain regions 51 and the gate electrode 18 from one another.

The gate spacer 40 may be formed of at least one of an oxide, a nitride, or an oxynitride, and may be formed of a low-k film. The gate spacer 40 may include, for example, at least one of SiO, SiN, SiCN, SiOC, SiON, or SiOCN.

Referring to FIGS. 2 and 3, the gate spacer 40 may have a multilayer structure, in example embodiments. The gate spacer 40 may include a plurality of spacers. For example, the gate spacer 40 may include a first spacer (or ‘inner side spacer’ 42), a second spacer (or ‘intermediate spacer’ 44) on the first spacer 42, and a third spacer (or ‘outer side spacer’ 46) on the second spacer 44. For example, each of the first and second gate spacers of the gate spacer 40 may include the first spacer 42, the second spacer 44 on the first spacer 42, and the third spacer 46 on the second spacer 44. However, example embodiments thereof is not limited thereto.

The first spacer 42 may be disposed on the second active region 10b and may cover one side surface of the gate structure GS on the second active region 10b. In example embodiments, referring to FIGS. 2 and 3, the first spacer 42 may include a first vertical portion 42V in contact with the gate electrode 18, and a first horizontal portion 42H extending from a lower end portion of the first vertical portion 42V.

Referring to FIG. 3, the first spacer 42 may be formed in a single layer or multiple layers. The first spacer 42 may include at least one layer. For example, the first spacer 42 may have a first spacer layer 42a of a nitride series and a second spacer layer 42b of an oxide series and disposed on the first spacer layer 42a. The first spacer 42 may further have a third spacer layer 42c of a nitride series on the second spacer layer 42b of an oxide series. However, the structure of the first spacer is not limited thereto, and in other examples, the second spacer layer 42b may not be provided.

The second spacer 44 may be disposed on the second active region 10b. In some example embodiments, the second spacer 44 may be in contact with the first horizontal portion 42H and the first vertical portion 42V of the first spacer 42.

The third spacer 46 may extend while covering an external side surface of the second spacer 44. The third spacer 46 may extend between the source/drain regions 51 and the gate structure GS. For example, at least a partial region of the external side surface of the third spacer 46 included in the first gate spacer 40a may be in contact with the first source/drain region 51a, and at least a partial region of the external side surface of the third spacer 46 included in the second gate spacer 40b may be in contact with the second source/drain region 51b. At least a partial region of an internal side surface of the third spacer 46 may be in contact with the second active region 10b. Accordingly, the external side surface of the third spacer 46 may be in contact with the source/drain regions 51, the internal side surface of the third spacer 46 may be in contact with the second active region 10b, and accordingly, in the third spacer 46, the first and second source/drain regions 51a and 51b and the second active region 10b may be spaced apart from one another in the horizontal direction (e.g., X-direction).

In some example embodiments, the first spacer 42 may have a first thickness, the second spacer 44 may have a second thickness greater than the first thickness, and the third spacer 46 may have a third thickness less than the first thickness. A lower surface of the third spacer 46 may be at a level lower than a level of a lower surface of the first spacer 42 and the second spacer 44.

In this case, the third thickness may be about 3 nm to 9 nm. In some example embodiments, when the thickness of the third spacer 46 is less than 3 nm, sufficient spacing distance may not be ensured due to the small spacer thickness of less than 3 nm, such that physical separation between the second active region 10b and the source/drain regions 51 may be significantly reduced. Accordingly, reliability of the elements may be reduced. When the thickness of the third spacer 46 is 9 nm or more, electrical properties of the element may be degraded due to the excessive spacer thickness, such that resistance of the source/drain region may increase and current driving force may degrade.

By disposing the third spacer 46 such that the first and second source/drain regions 51a and 51b are spaced apart from the second active region 10b, the third spacer 46 may reduce defects or strain non-uniformities which may occur in the second active region 10b. Accordingly, electrical properties of the channel region formed in the second active region 10b may be stably maintained, and performance consistency of the semiconductor device and yield of the semiconductor device may be improved. Also, excessive strain which may occur during the process of forming the source/drain regions 51 may cause physical damage to the gate spacer 40 and the second active region 10b, but as the third spacer 46 may allow the second active region 10b and the source/drain regions 51 to be spaced apart from one another, the above issue may be prevented. This design may contribute to extension of lifespan of the elements and improvement of reliability.

Also, by disposing the third spacer 46 such that the source/drain regions 51 are spaced apart from the second active region 10b, the short channel effect (SCE) occurring when the length of the channel region in the transistor decreases may be prevented. Ensuring of an appropriate distance between the second active region 10b and the source/drain regions 51 may optimize strain transfer and may also stably maintain electrical properties of the channel. In particular, by disposing the third spacer 46, electric field concentration in the channel region and threshold voltage (Vth) reduction, which may be caused as the source/drain regions 51 penetrate the second active region 10b and have a shorter distance than the designed second active region 10b, may be alleviated, which may contribute to reducing short channel effects such as current leakage or drain-induced barrier lowering (DIBL). Also, the spacing structure by the third spacer 46 may improve gate control ability of the channel, such that high performance and low power properties may be maintained even in a miniaturized element.

The materials of the first and third spacers 42 and 46 may be different from the material of the second spacer 44. For example, the first and third spacers 42 and 46 may include a first insulating material of a nitride or nitride series, and the second spacer 44 may include a second insulating material of an oxide or oxide series. For example, the first insulating material may include silicon nitride, and the second insulating material may include silicon oxide. Also, each of the first to third spacers 42, 44, and 46 may be formed as a single layer or multiple layers.

The interlayer insulating layer 60 may be disposed on the third spacer 46. For example, the interlayer insulating layer 60 may cover the gate spacer 40, the source/drain regions 51, and the device isolation layer 6.

The interlayer insulating layer 60 may be formed of silicon oxide or a low-k dielectric having a dielectric constant smaller than that of silicon oxide.

The upper capping insulating layer 63 may be disposed on the interlayer insulating layer 60.

The upper capping insulating layer 63 may include a material different from that of the interlayer insulating layer 60, for example, silicon nitride.

The semiconductor device 100 according to example embodiments may further include contact structures 66 penetrating the upper capping insulating layer 63 and the interlayer insulating layer 60 in order and electrically connected to the source/drain regions 51, and an interlayer insulating layer 60.

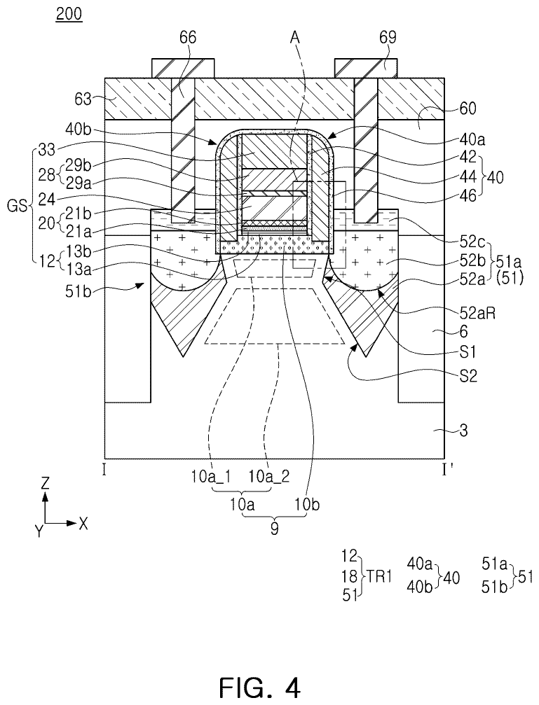

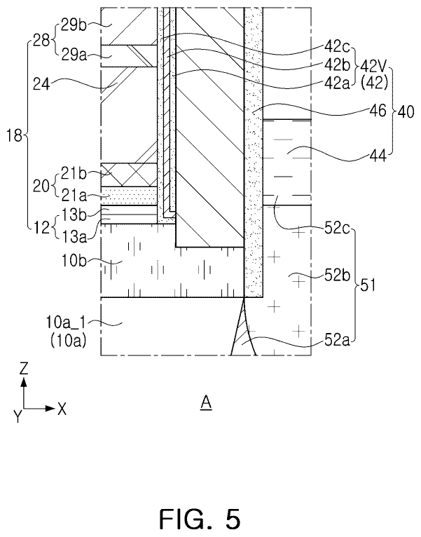

FIG. 4 is a cross-sectional diagram illustrating a semiconductor device according to example embodiments. FIG. 5 is an enlarged diagram illustrating region ‘A’ in FIG. 4.

Referring to FIGS. 4 and 5, the semiconductor device 200 may be configured similarly to the semiconductor device 100 illustrated in FIGS. 1 to 3, other than the configuration in which the second spacer 44 is disposed in a position in which the first horizontal portion (42H, see FIGS. 2 and 3) extending from an end portion of the first vertical portion 42V of the first spacer 42 is positioned, and a level of the lower surface of the second spacer 44 is lower than a level of the lower surface of the first spacer 42. Accordingly, the description of the semiconductor device 100 illustrated in FIGS. 1 to 3 may be combined with the description of the semiconductor device 200 according to the example embodiment, unless otherwise indicated.

The first spacer 42 of the semiconductor device 200 may include only the first vertical portion 42V. Also, the first spacer 42 may cover a side surface of the gate structure GS, may be disposed on the second active region 10b, and may include a second spacer 44 covering an external side surface of the first spacer 42, a lower surface of the second spacer 44 may be in contact with the second active region 10b, at least a portion of an internal side surface of the second spacer 44 may be in contact with a side surface of the second active region 10b, and a level of a lower surface of the second spacer 44 may be lower than a level of a lower surface of the gate electrode 18. A level of a lower surface of the second spacer 44 may be lower than a level of a lower surface of the gate structure (GS, see FIG. 2).

In the case of the first horizontal portion (42H, see FIGS. 2 and 3), when an ion implantation process is performed during the process of forming the semiconductor device, damage may accumulate due to continuous collisions with ions. Accordingly, the structure of the first spacer 42 may collapse, which may reduce reliability of the semiconductor device. By disposing the second spacer 44 instead of the first horizontal portion (42H, see FIGS. 2 and 3), the spacer in which damage is not accumulated may be disposed, thereby ensuring reliability of the semiconductor device. When removing the first horizontal portion (42H, see FIGS. 2 and 3) and disposing the second spacer 44, when the first spacer 42 is formed in multiple layers, some layers having a horizontal portion may be present.

Accordingly, in the semiconductor device 200 in example embodiments, by disposing the second spacer 44 instead of the first horizontal portion (42H, see FIGS. 2 and 3), a structure of the spacer of the semiconductor device may be stably formed, thereby improving reliability.

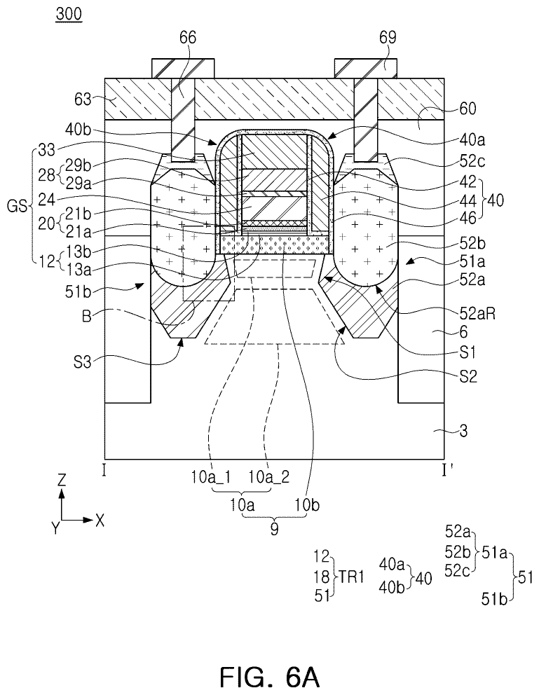

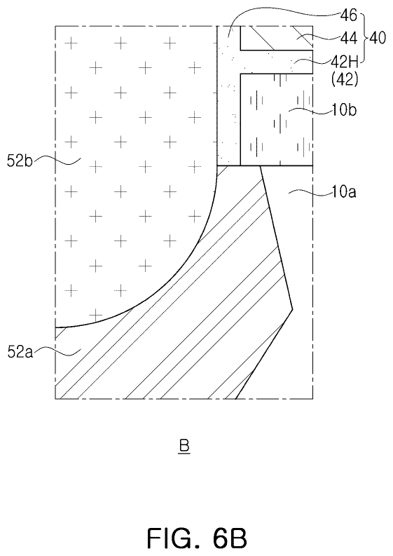

FIG. 6A is a cross-sectional diagram illustrating a semiconductor device according to example embodiments. FIG. 6B is an enlarged diagram illustrating region ‘B’ in FIG. 6A.

Referring to FIGS. 6A and 6B, the semiconductor device 300 may be configured similarly to the semiconductor device 100 illustrated in FIGS. 1 to 3, other than the configuration in which a portion of the structure of the epitaxial patterns 52a, 52b, and 52c of the source/drain regions 51 is different. Accordingly, the description of the semiconductor device 100 illustrated in FIGS. 1 to 3 may be combined with the description of the semiconductor device 300 according to the example embodiment, unless otherwise indicated.

A lower surface of the second active region 10b of the semiconductor device 300 may include a region in contact with the first and second source/drain regions 51a and 51b. In example embodiments, the second epitaxial patterns 52b and the second active region 10b, included in the source/drain regions 51, respectively, may be spaced apart from one another by the third spacer 46, and the first epitaxial pattern 52a and the second active region 10b may be in contact with one another.

When forming the source/drain regions 51, a recess may be formed below the second active region 10b. Accordingly, the first epitaxial pattern 52a may be formed to be in contact with a lower surface of the second active region 10b exposed by the recess. Depending on the structure in which the recess is formed, a portion of a lower surface of the source/drain regions 51 may include a {100} crystal plane. For example, a lower surface S3 of the first epitaxial pattern 52a of the source/drain regions 51 may be one of a (−1 0 0) plane, (0 1 0) plane, (0 −1 0) plane, (0 0 1) plane, or (0 0 −1) plane.

Also, the second epitaxial pattern 52b may protrude upwardly, and the third epitaxial pattern 52c disposed on the second epitaxial pattern 52b may also protrude along the protruding shape of the second epitaxial pattern 52b. The height of the source/drain regions 51 may be relatively larger than that of the semiconductor device 100 illustrated in FIGS. 1 to 3. The second and third epitaxial patterns 52b and 52c may have shapes of which widths may increase in the third direction (e.g., Z-direction) toward the substrate 3. This may be a shape formed due to differences in growth rates between crystal planes as the source/drain regions 51 are formed by an epitaxial growth method. However, example embodiments thereof is not limited thereto.

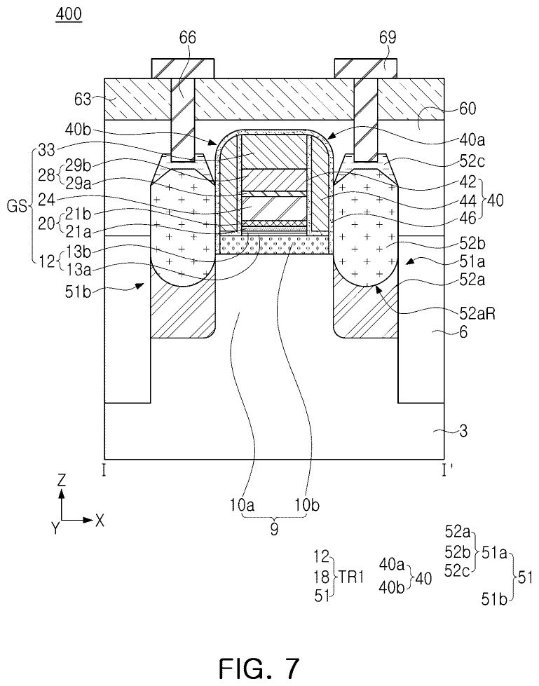

FIG. 7 is a cross-sectional diagram illustrating a semiconductor device according to example embodiments.

Referring to FIG. 7, a semiconductor device 400 may be configured similarly to the semiconductor device 300 illustrated in FIGS. 6A and 6B, other than the configuration in which the shape of the epitaxial pattern 52a of the source/drain regions 51 is partially different. Accordingly, the description of the semiconductor device 100 illustrated in FIGS. 6A and 6B may be combined with the description of the semiconductor device 300 according to the example embodiment, unless otherwise indicated.

Depending on characteristics of an etching process (or recess process) performed on the active region 9 to form the first epitaxial pattern 52a, a width in the first direction (e.g., X-direction) of the first epitaxial pattern 52a may be constant toward the substrate 3.

The width of the first active region 10a may be substantially maintained the same even when the first active region 10a is spaced apart from the second active region 10b. For example, a width of the portion corresponding to the first region 10a_1 in FIG. 6A may not decrease toward the substrate 3, and a width of the portion corresponding to the second region 10a_2 in FIG. 6A may also not increase toward the substrate 3, differently from the semiconductor device 300 in FIG. 6A. This may be referred to as a box-type source/drain regions 51, but example embodiments thereof is not limited thereto.

The first epitaxial pattern 52a may be in contact with a side surface of the first active region 10a. The first epitaxial pattern 52a may be disposed on the side surface of the first active region 10a and spaced apart from the second active region 10b. For example, the first epitaxial pattern 52a may be spaced apart from a lower surface of the second active region 10b disposed below the gate structure 160.

Referring to FIGS. 6A and 6B together with FIG. 7, when the shape of the source/drain regions 51 illustrated in FIG. 6A is referred to as a sigma (2)-type, the shape of the source/drain regions 51 in FIG. 7 may be referred to as a box-type. When the first epitaxial pattern 52a is formed to have the box-type source/drain regions 51, manufacturing costs may be reduced and process stability may be increased as compared to the sigma (Σ)-type source/drain regions 51.

When the box-type source/drain regions 51 are formed, the source/drain regions may be grown directly without a selective etching process differently from the sigma (Σ)-type, such that the process may be simplified and the manufacturing costs may be reduced. Also, since the source/drain regions 51 are formed without a selective etching process, the source/drain regions 51 having a uniform shape may be formed, which may reduce process variability. For example, compressive stress in the box-type source/drain regions 51 may be lower than that of the sigma (Σ)-type, such that hole mobility of the pFET may be lowered accordingly, but this may be adopted for process stability. In this case, stress in the sigma (Σ)-type source/drain regions 51 may be about 1.1 GPa to 1.4 GPa, and stress in the box-type source/drain regions 51 may be about 0.9 GPa to 1.1 GPa. In example embodiments, the stress due to the sigma (Σ)-type source/drain regions 51 may be about 1.22 GPa, and the stress due to the box-type source/drain regions 51 may be about 1.04 GPa.

In example embodiments, the sigma (Σ)-type source/drain regions 51 may be applied for a high-performance pFET using strong compressive stress, and the box-type source/drain regions 51 may be used for a low-power pFET, but the structure of the gate spacer 40 may be applied regardless of the shape of the source/drain regions 51.

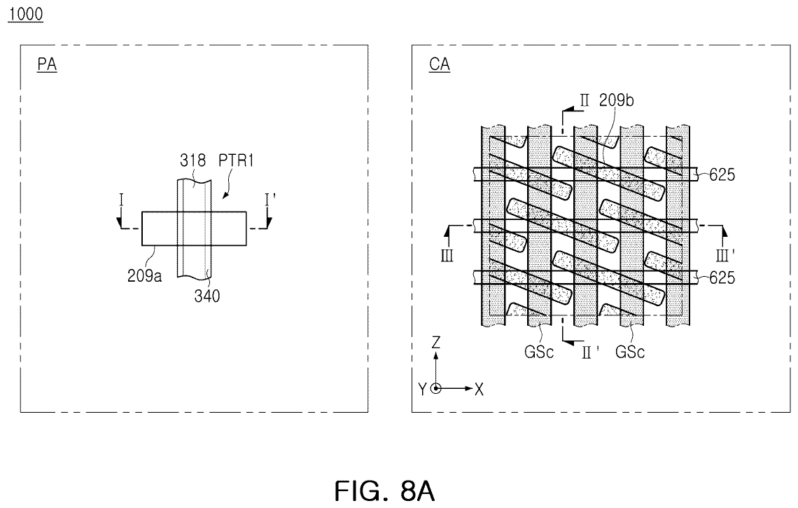

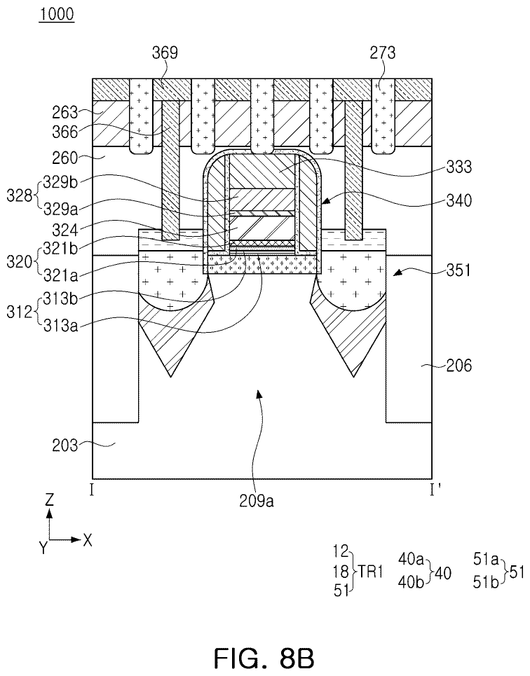

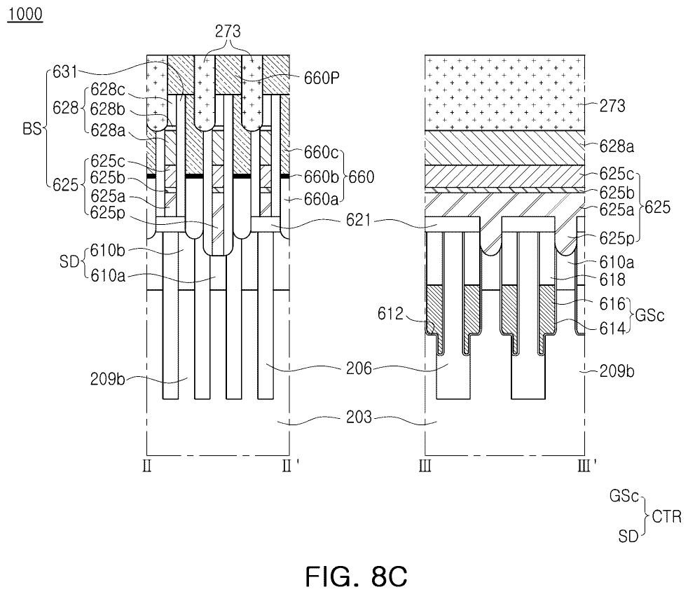

FIG. 8A is a plan diagram illustrating a semiconductor device according to example embodiments. FIG. 8B is a cross-sectional diagram taken along line I-I′ in FIG. 8A. FIG. 8C is a cross-sectional diagram illustrating sections taken along lines II-II′ and III-III′ in FIG. 8A.

Referring to FIGS. 8A to 8C, a semiconductor device 1000 according to example embodiments may include a substrate 203 having a memory cell region CA and a peripheral circuit region PA, and a device isolation layer 206 defining a cell active region 209b on the memory cell region CA of the substrate 203 and defining a peripheral active region 209a on the peripheral circuit region PA of the substrate 203. The substrate 203 may be configured as a semiconductor substrate. The cell active region 209b and the peripheral active region 209a may have a shape protruding in a vertical direction Z from the substrate 203. A plurality of the cell active regions 209b and a plurality of the peripheral active regions 209a may be disposed in the cell region CA and the peripheral circuit region PA, respectively. The device isolation layer 206 may be formed by shallow trench isolation. The device isolation layer 206 may be formed of an insulating material, such as silicon oxide and/or silicon nitride.

The semiconductor device 1000 according to example embodiments may include a cell gate structure GSc and a cell gate capping pattern 618 on the cell gate structure GSc buried in the cell active region 209b on the memory cell region CA and extending into the device isolation layer 206. The cell gate structure GSc and the cell gate capping pattern 618 may be disposed in a cell gate trench 612 crossing the cell active region 209b and extending into the device isolation layer 206.

Each of the cell gate structures GSc may include a cell gate dielectric layer 614 conformally covering an internal wall of the cell gate trench 612 and a cell gate electrode 616 partially filling the cell gate trench 612 on the cell gate dielectric layer 614.

The cell gate electrode 616 may be a wordline of a memory semiconductor device such as a DRAM.

The cell gate electrode 616 may include doped polysilicon, a metal, a conductive metal nitride, a metal-semiconductor compound, a conductive metal oxide, graphene, carbon nanotubes (CARbon nanotubes) or a combination thereof. For example, the cell gate electrode 616 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, carbon nanotubes or a combination thereof, but example embodiments thereof is not limited thereto. The cell gate electrode 616 may include a single layer or multiple layers of the materials mentioned above. The cell gate capping pattern 618 may include an insulating material, for example, silicon nitride.

The semiconductor device 1000 according to example embodiments may further include cell source/drains SD including a first impurity region 610a and a second impurity region 610b disposed in the cell active region 209b on the memory cell region CA.

The cell gate structure GSc and the cell source/drains SD may form cell transistors CTR.

The semiconductor device 1000 according to example embodiments may further include, on the memory cell region CA, a buffer insulating layer 621 on the cell active region 209b and the device isolation layer 206, an interconnection structure BS including a bitline plug portion 625p disposed on the buffer insulating layer 621 and penetrating the buffer insulating layer 621, cell contact structures 660 disposed on both sides of the interconnection structure BS, pad portions 660P overlapping a portion of the interconnection structure BS and electrically connected to the cell contact structures 660, and an insulating isolation structure 273 disposed between the pad portions 660P and extending downwardly.

Each of the interconnection structures BS may include a conductive line 625, an interconnection capping layer 628, and insulating spacers 631 on side surfaces of the conductive line 625 and the interconnection capping layer 628, stacked in order.

In each of the interconnection structures BS, the conductive line 625 may include a first layer 625a, a second layer 625b and a third layer 625c, stacked in order, and the bitline plug portion 625p may extend downwardly from a portion a of the first layer 625a and may be electrically connected to the first impurity region 610a of the first source/drain SD.

In the conductive line 625, the first layer 625a may be formed of a doped silicon layer, the second layer 625b may be formed of a metal nitride and/or metal-semiconductor compound layer (e.g., WN, TiN, WSi, TiSi, and/or TiSiN, or the like), and the third layer 625c may be formed of a metal layer (e.g., W, or the like).

In example embodiments, the interconnection structures BS may be bitline structures. For example, the conductive line 625 may be configured as a bitline including the bitline plug portion 625p electrically connected to the first impurity region 610a. The conductive line 625 may be configured as a bitline of a memory element such as a DRAM, or the like.

The interconnection capping layer 628 may include a first layer 628a, a second layer 628b and a third layer 628c, stacked in order. The interconnection capping layer 628 may be formed of an insulating material of silicon nitride and/or silicon nitride series.

The PMOS transistor PTR1 may have substantially the same structure as that of the transistor TR1, configured as a PMOS transistor, described with reference to FIG. 1. For example, the PMOS transistor PTR1 may include a PMOS gate dielectric pattern 312 on the peripheral active region 209a, a PMOS gate electrode 318 on the PMOS gate dielectric pattern 312, a PMOS gate spacer 340 covering both sides of the PMOS gate electrode 318 and PMOS peripheral source/drain regions 351 disposed on the peripheral active region 209a adjacent to the PMOS gate spacer 340.

The PMOS gate dielectric pattern 312 may include a PMOS lower dielectric layer 313a and a PMOS upper dielectric layer 313b, which may correspond to the lower dielectric layer 13a and the upper dielectric layer 13b described with reference to FIG. 1, respectively. The PMOS lower conductive pattern 320 may include a PMOS lower conductive layer 321a and a second PMOS lower conductive layer 321b, which may correspond to the lower conductive layer 21a and the second lower conductive layer 21b described with reference to FIG. 1, respectively. The PMOS intermediate conductive pattern 324 may include a PMOS intermediate portion 325a and a second PMOS intermediate portion 325b, which may correspond to the intermediate portion 25a and the second intermediate portion 25b described with reference to FIG. 1, respectively. The PMOS upper conductive pattern 328 may include a PMOS upper conductive layer 329a and a second PMOS upper conductive layer 329b, which may correspond to the upper conductive layer 29a and the second upper conductive layer 29b described with reference to FIG. 1, respectively.

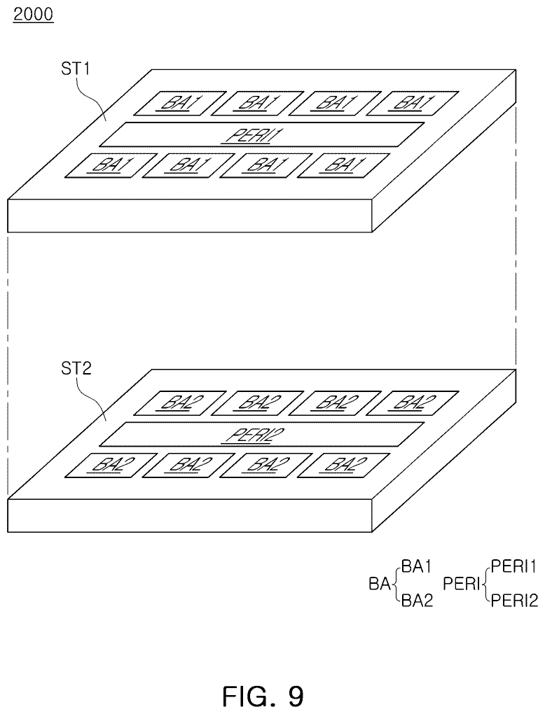

FIG. 9 is a perspective diagram illustrating a semiconductor device according to example embodiments.

Referring to FIG. 9, a semiconductor device 2000 according to example embodiments may include a first structure ST1 and a second structure ST2 vertically overlapping the first structure ST1. The second structure ST2 may be disposed below the first structure ST1. In example embodiments, the second structure ST2 may be disposed on the first structure ST1. In example embodiments, the first structure ST1 may be a first chip structure including a memory region and a peripheral region, and the second structure ST2 may be a second chip structure including a peripheral circuit. The first structure ST1 and the second structure ST2 may be bonded to one another by a bonding process, such as a wafer bonding process. Accordingly, the first structure ST1 may be in contact with and bonded to the second structure ST2.

The semiconductor device 2000 may include a plurality of banks BA and an outer peripheral region PERI. The outer peripheral region PERI may include a first peripheral region PERI1 in the first structure ST1 and a second peripheral region PERI2 in the second structure ST2. The outer peripheral region PERI may be a peripheral region in which peripheral circuits for input and output of data or commands, or input of power/ground, are disposed. Each of the plurality of banks BA may include a first bank region BA1 in the first structure ST1 and a second bank region BA2 in the second structure ST2. The first bank region BA1 in the first structure ST1 may include memory cells. The second bank region BA2 in the second structure ST2 may include peripheral circuits such as a sense amplifier and a sub-wordline driver.

The first structure ST1 of the semiconductor device 2000 may include a memory region and a peripheral region. Hereinafter, the memory region in the first bank region BA1 of the first structure ST1 of the semiconductor device 1000 and the second structure ST2 perpendicular thereto will be described.

The second structure ST2 may include a first peripheral circuit vertically overlapping the memory region. The PMOS transistor included in the first peripheral circuit may be substantially the same structure as that of the transistor (TR1, see FIG. 2), a PMOS transistor, described with reference to FIG. 2.

As illustrated in FIGS. 8A to 8C, the memory cell region CA and the peripheral circuit region PA may be formed on the same substrate 203. Also, referring to FIG. 9, the memory cell region CA, FIG. 8A, and the peripheral circuit region PA, FIG. 8A, may be applied to a conventional DRAM process in which the memory region is formed on the peripheral circuit and also to a structure in which the memory region is formed on the peripheral circuit. For example, the transistor (TR1, see FIG. 2) reflecting the technical idea of the example embodiments may be applied to a cell-on-periphery (COP) DRAM structure or a periphery-on-cell (POC) DRAM structure. Specifically, the transistor may also be applied to a structure in which a memory cell and a peripheral circuit are formed on different substrates and bonded to one another through wafer bonding.

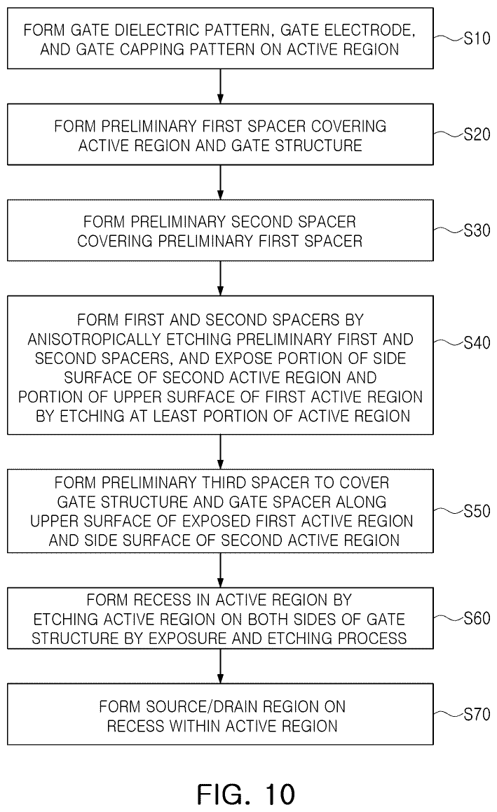

FIG. 10 is a process flowchart illustrating main processes of a method of manufacturing a semiconductor device according to example embodiments.

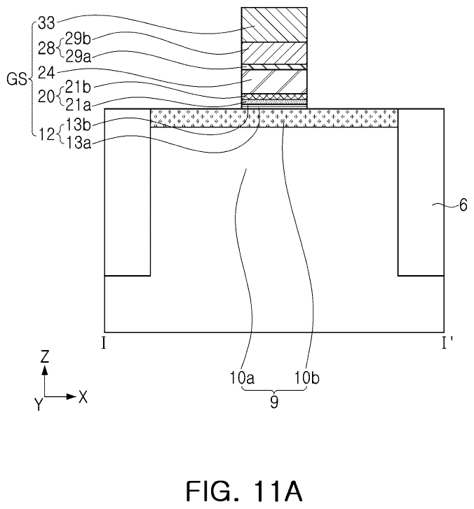

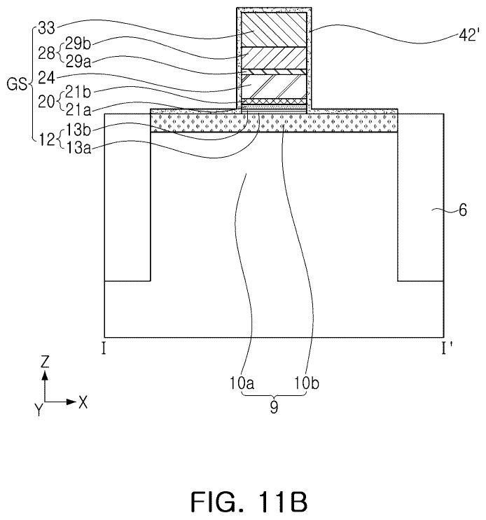

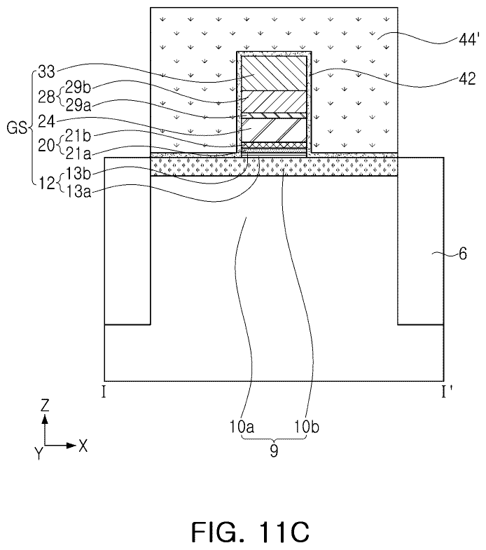

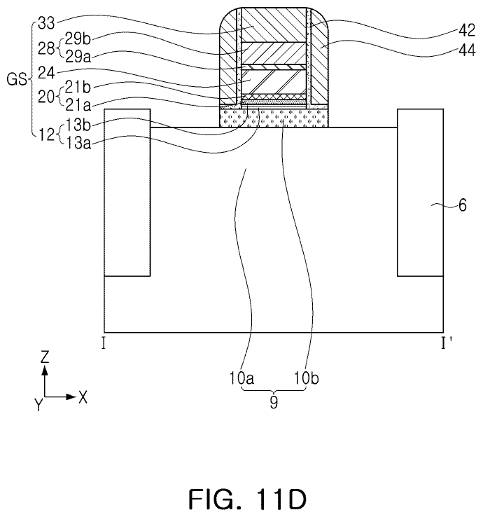

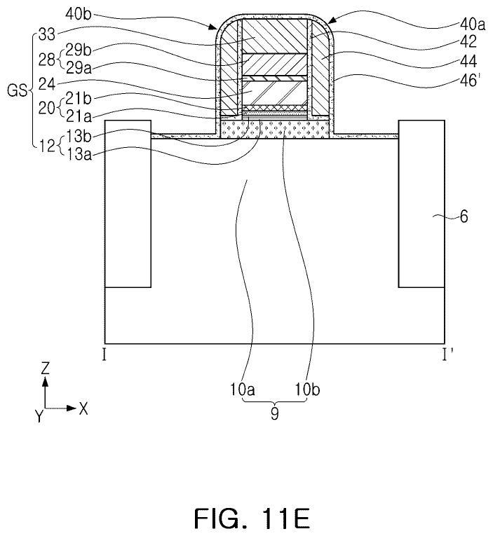

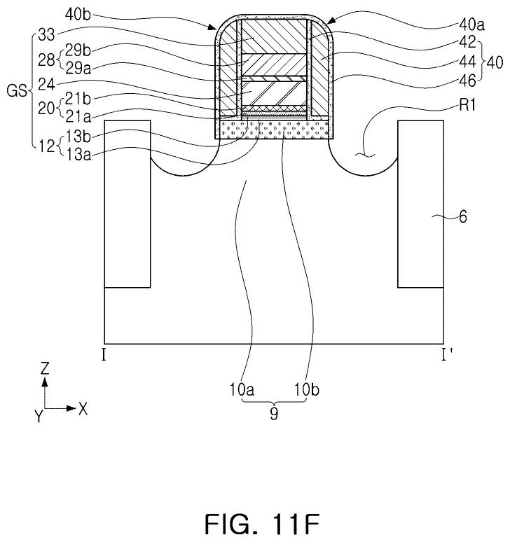

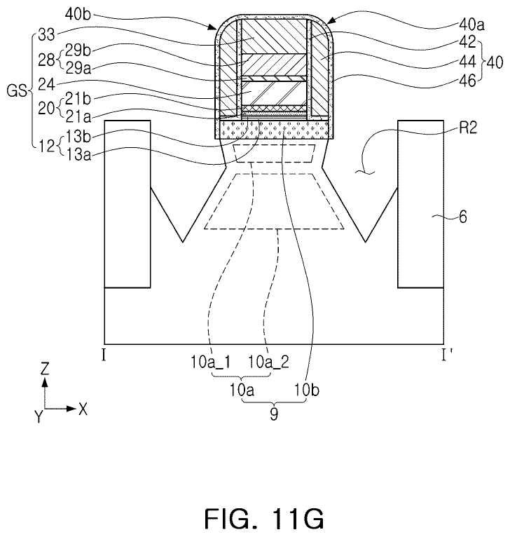

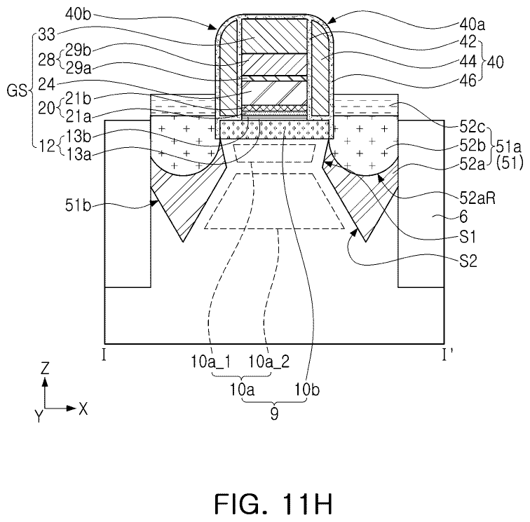

FIGS. 11A to 11H are cross-sectional diagrams illustrating processes of manufacturing a semiconductor device according to example embodiments. FIGS. 11A to 11H describe example embodiments of a manufacturing method of manufacturing the semiconductor devices in FIGS. 1 to 3, and illustrate cross-sectional surfaces corresponding to FIG. 2.

Referring to FIGS. 10 and 11A, a gate dielectric pattern 12, a gate electrode 18, and a gate capping pattern 33 may be formed on an active region 9 (S10). A trench defining the active region 9 may be formed by etching a portion of substrate 3, and the active region 9 may be formed by forming a device isolation layer 6 filling the trench.

Layers included in each of the gate dielectric pattern 12 and the gate electrode 18 may be formed in order on the active region 9, and a gate capping pattern 33 may be formed. At least a portion of layers included in each of the gate dielectric pattern 12 and the gate electrode 18 may be etched by an etching process using the gate capping pattern 33 as an etching mask, thereby forming a gate structure GS including the gate electrode 18, the gate dielectric pattern 12 and the gate capping pattern 33 on the active region 9.

Referring to FIGS. 10 and 11B, a preliminary first spacer 42′ covering the active region 9 and the gate structure GS including the active region 9, the gate dielectric pattern 12, the gate electrode 18 and the gate capping pattern 33 may be formed (S20). Referring to FIGS. 10 and 11B, the preliminary first spacer 42 may be formed on the second active region 10b and may cover one side surface and an upper surface of the gate structure GS on the second active region 10b. Referring to FIG. 3, the preliminary first spacer 42′ may be formed in a single layer or multiple layers. The preliminary first spacer 42′ may include at least one layer.

Thereafter, low-concentration impurity regions may be formed in the active region 9 by performing a low-concentration ion implantation process. Thereafter, Halo ion implantation may also be performed. When the ion implantation process is performed, damage may be applied to a horizontal portion of the preliminary first spacer 42′ due to continuous collision with ions. Such damage may weaken the physical structure of the spacer and may deteriorate uniformity in the subsequent process. In particular, the horizontal portion of the preliminary first spacer 42′ may be further exposed to ion collisions than a vertical portion formed on a side surface of the gate structure GS, such that structural defects may be concentrated. Accordingly, the damaged spacer may have a negative impact on reliability and performance of the process.

Referring to FIGS. 10 and 11C, a preliminary second spacer 44′ covering the preliminary first spacer 42′ may be formed (S30). A film having a uniform thickness may be formed along the second active region 10b and the gate structure GS while covering the preliminary first spacer 42′.

A material of the preliminary first spacer 42′ may be different from a material of the preliminary second spacer 44′. For example, the preliminary first spacer 42′ may include a first insulating material of a nitride or nitride series, and the preliminary second spacer 44′ may include a second insulating material of an oxide or oxide series. For example, the first insulating material may include silicon nitride, and the second insulating material may include silicon oxide. Also, example embodiments thereof is not limited thereto, and each of the preliminary first and second spacers 42′ and 44′ may be formed in a single layer or multiple layers.

Referring to FIGS. 10 and 11D, the first and second spacers 42, 44 may be formed by anisotropically etching the preliminary first and second spacers 42′ and 44′, and a portion of a side surface of the second active region 10b and a portion of an upper surface of the first active region may be exposed by etching at least a portion of the active region 9 (S40). The preliminary first and second spacers 42′ and 44′ may be etched, and further, the exposed second active region 10b may be etched such that the first active region 10a may be exposed.

The first spacer 42 may be disposed on the second active region 10b, and may cover one side surface of the gate structure GS on the second active region 10b. In example embodiments, the first spacer 42 may include a first vertical portion 42V in contact with the gate electrode 18 and a first horizontal portion 42H extending from a lower end portion of the first vertical portion 42V.

The second spacer 44 may be disposed on the second active region 10b. In some example embodiments, the second spacer 44 may be in contact with the first horizontal portion 42H and the first vertical portion 42V of the first spacer 42 on the first horizontal portion 42H.

Referring to FIGS. 10 and 11E, the preliminary third spacer 46′ may be formed to cover the gate structure GS and the gate spacer 40 along a side surface of the exposed first active region 10a and second active region 10b (S50).

More specifically, in this case, a thickness of the etched second active region 10b may be at least 8 nm or more. The preliminary third spacer 46′ may be conformally formed on an upper surface of the exposed active region 9, external side surfaces of the gate spacer 40 covering a side surface of the gate structure GS, and an upper surface of the gate capping pattern 33. A lower surface of the first spacer 42 may be formed to be at a level least 8 nm higher than a level of a lower surface of the preliminary third spacer 46′.

Referring to FIGS. 10, 11F and 11G, the active region 9 on both sides of the gate structure GS may be etched by an exposure and etching process, thereby forming a recess in the active region 9 (S60).

Referring to FIG. 11F, a photoresist may be applied on the active region 9 to form a recess in which the source/drain regions (51, see FIG. 2) are positioned, and the first recesses R1 may be formed on both side surfaces of the gate structure GS and gate spacer 40 by patterning the photoresist by exposure and development. The active region 9 may be etched using a mask pattern as an etching mask. In this case, the etching process of the active region 9 to be performed may be dry etching.

Thereafter, the photoresist may be removed using an ashing and stripping process, and the first recess R1 in the active region 9 may be etched. Accordingly, a second recess R2 in which the source/drain regions (51, see FIG. 2) are formed may be formed. In this case, a first region (10a_1, see FIG. 2) and a second region (10a_2, see FIG. 2) may be formed in the first active region 10a.

In example embodiments, the first region (10a_1, see FIG. 2) may have a first surface. In example embodiments, the first surfaces may include a {110} crystal plane. For example, the first surface may be one of a (1 1 0) plane, (−1 1 0) plane, (1 −1 0) plane, (−1 −1 0) plane, (1 0 1) plane, (−1 0 1) plane, (1 0 −1) plane, (−1 0 −1) plane, (0 1 1) plane, (0 1 −1) plane, (0 1 −1) plane, and (0 −1 −1) plane.

The second region (10a_2, see FIG. 2) may have a second surface below the first surface. In example embodiments, the first and second surfaces may include a {111} crystal plane. For example, the second inclined surface 152s may be one of a (1 1 1) plane, (1 1 −1) plane, (1 −1 1) plane, (1 −1 −1) plane, (−1 1 1) plane, (−1 1 −1) plane, (−1 −1 1) plane, and (−1 −1 −1) plane. The etching process performed herein may be wet etching.

Referring to FIGS. 10 and 11H, source/drain regions 51 may be formed on a recess R2 within the active region 9 (S70).

The first epitaxial pattern 52a may be formed on an upper surface of the recess and at least one side surface (e.g., both side surfaces) of the gate spacer 40. The first epitaxial pattern 52a may include an epitaxial layer. For example, the first epitaxial pattern 52a may be formed from the active region 9 by an epitaxial growth method. Also, the first epitaxial pattern 52a may be disposed on a side surface of the first active region 10a and may be connected to the second active region 10b. For example, the first epitaxial pattern 52a may be connected to a lower surface of the second active region 10b disposed below the gate structure 160.

The second epitaxial pattern 52b may be formed on the first epitaxial pattern 52a. The second epitaxial pattern 52b may be formed to fill the space formed by the recessed surface of the first epitaxial pattern 52a. A partial side surface of the second epitaxial pattern 52b may be formed to be in contact with an external side surface of the third spacer 46. The second epitaxial pattern 52b may overlap in the first direction (e.g., X-direction). The second epitaxial pattern 52b may be connected to the first epitaxial pattern 52a.

The third epitaxial pattern 52c may be formed on the second epitaxial pattern 52b. A partial side surface of the third epitaxial pattern 52c may be in contact with an external side surface of the third spacer 46. A lower surface of the third epitaxial pattern 52c may be connected to an upper surface of the second epitaxial pattern 52b.

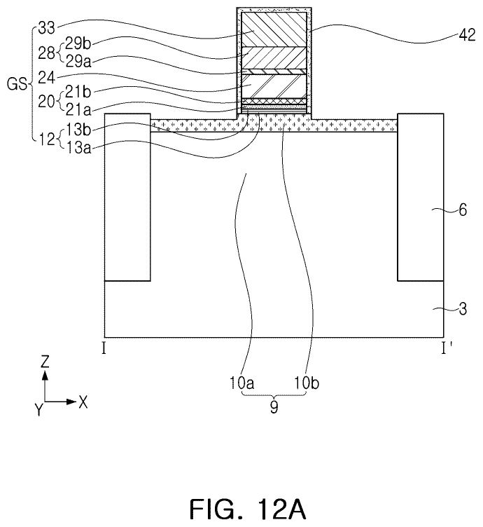

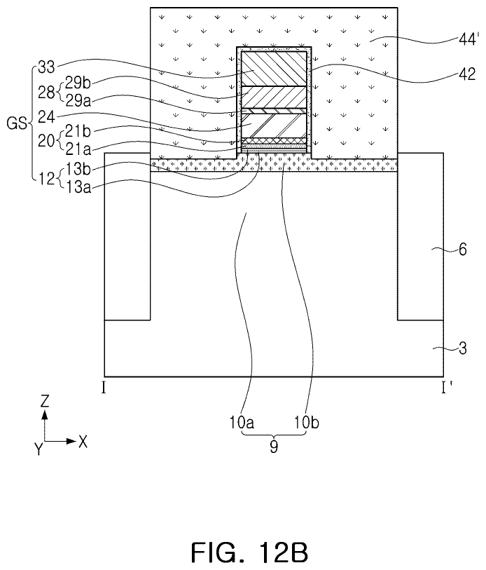

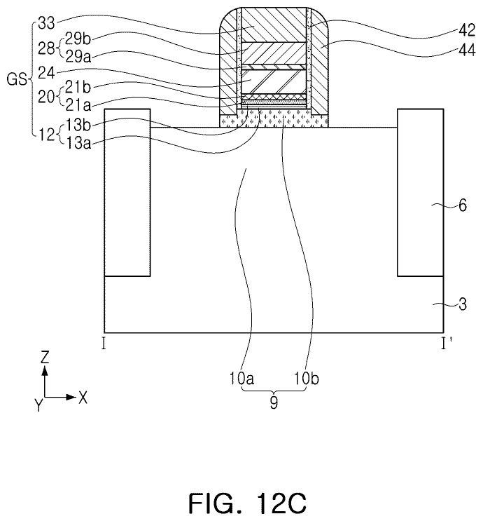

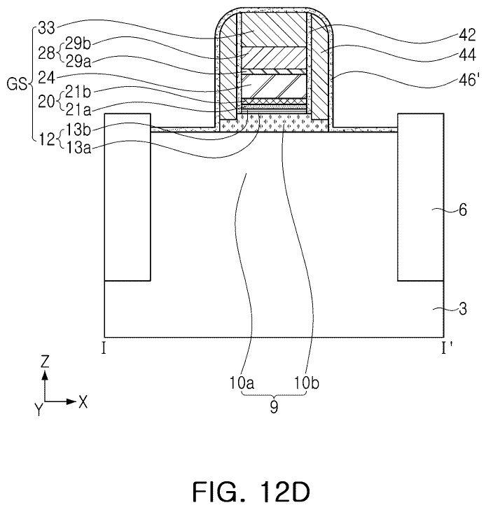

FIGS. 12A to 12D are cross-sectional diagrams illustrating processes of manufacturing a semiconductor device according to example embodiments. FIGS. 12A to 12D illustrate an example of a manufacturing method for manufacturing the semiconductor device in FIGS. 1 to 3, and illustrate cross-sectional surfaces corresponding to FIG. 2.

Referring to FIGS. 10, 11A, and 11B, a active region covering the active region 9 and a gate dielectric pattern 12, a gate electrode 18, and a gate capping pattern 33, and a preliminary first spacer 42′ covering the gate structure GS may be formed. Thereafter, referring to FIG. 12A, a partial side surface of the second active region 10b may be exposed by etching the preliminary first spacer 42′ and the second active region 10b and a first spacer 42 may be formed.

More specifically, in this case, a thickness of the etched second active region 10b may be about 3 nm. The etching may be continued until a horizontal portion of the preliminary first spacer 42′ is removed. Accordingly, the preliminary first spacer 42′ damaged by the ion implantation process may be removed. In this case, the thickness of the etched second active region 10b may be for removing the horizontal portion of the preliminary first spacer 42′, and is not thus limited to the thickness value.

Thereafter, referring to FIGS. 12B and 12C, the preliminary second spacer 44′ may be applied and anisotropically etched, thereby forming the second spacer 44. Referring to FIG. 12B, the preliminary second spacer 44′ may be formed to cover the second active region 10b, which is etched and a portion of the side surface of which is partially exposed. In this case, the preliminary second spacer 44′ may be formed to cover a side surface and an upper surface of the first spacer 42 covering the gate structure GS. Referring to FIG. 12C, while etching the preliminary second spacer 44′, the second active region 10b of both sides of the gate structure GS and the gate spacer 42, 44 may be etched such that the first active region 10a may be exposed. More specifically, in this case, a thickness of the etched second active region 10b may be at least 8 nm or more. Accordingly, a partial side surface of the second active region 10b may also be exposed.

Referring to FIG. 12D, the preliminary third spacer 46′ may be formed to cover the gate structure GS and the gate spacer 40 along a side surface of the exposed first active region 10a and second active region 10b. A preliminary third spacer 46′ may be conformally formed on an upper surface of the exposed first active region 10a, a side surface of the second active region 10b, external side surfaces of the gate spacer 40 covering a side surface of the gate structure GS, and an upper surface of the gate capping pattern 33. A lower surface of the gate structure GS may be formed to be at a level at least 8 nm higher than a level of a lower surface of the preliminary third spacer 46′. However, example embodiments thereof is not limited thereto.

Referring further to FIGS. 4 and 5, the first spacer 42 of the semiconductor device 200 may include only a first vertical portion 42V. Also, the first spacer 42 may cover a side surface of the gate structure GS, may be formed on the second active region 10b, and may include a second spacer 44 covering an external side surface of the first spacer 42, a lower surface of the second spacer 44 may be in contact with the second active region 10b, at least a portion of an internal side surface of the second spacer 44 may be in contact with a side surface of the second active region 10b, and a lower surface of the second spacer 44 may be formed at a level lower than a level of a lower surface of the gate structure GS.

The second spacer 44′ may be formed after the preliminary first spacer 42′ etched, such that the second spacer 44 may be disposed, instead of the first horizontal portion (42H, see FIG. 2 and FIG. 3), thereby forming a spacer without accumulated damage. When removing the first horizontal portion (42H, see FIGS. 2 and 3) and forming the second spacer 44, when the first spacer 42 is formed in multiple layers, some of the layers having the horizontal portion may not be etched.

According to the aforementioned example embodiments, when forming a gate spacer, a portion of the gate spacer may be disposed between the channel region and the source/drain region of the semiconductor device, and may prevent penetration of the source/drain region into the lower portion of the gate spacer, thereby providing a semiconductor device having improved electrical properties and reliability.

While the example embodiments have been illustrated and described above, it will be configured as apparent to those skilled in the art that modifications and variations could be made without departing from the scope of the present disclosure as defined by the appended claims.

What is claimed is:

1. A semiconductor device, comprising:
a first source/drain region and a second source/drain region spaced apart from one another;
a first active region between the first source/drain region and the second source/drain region;
a second active region on the first active region;
a gate structure on the second active region; and
a first gate spacer on a first side surface of the gate structure and a second gate spacer on a second side surface of the gate structure,
wherein each of the first and second gate spacers includes a first spacer on the second active region, and a second spacer covering an external side surface of the first spacer and covering a side surface of the second active region.

2. The semiconductor device of claim 1,
wherein: the first active region includes a first material,
the second active region includes a second material different from the first material, and
the second spacer allows the first and second source/drain regions and the second active region to be spaced apart from one another in a horizontal direction.

3. The semiconductor device of claim 2,
wherein:
the first material includes silicon,
the second material includes a first silicon-germanium, and
the first and second source/drain regions include a second silicon-germanium.

4. The semiconductor device of claim 1,
wherein:
the second spacer of the first gate spacer is in contact with the first source/drain region, and
the second spacer of the second gate spacer is in contact with the second source/drain region.

5. The semiconductor device of claim 1, wherein a portion of a lower surface of the second active region includes a region in contact with the first source/drain region and the second source/drain region.

6. The semiconductor device of claim 1, wherein the first spacer covers a side surface of the gate structure and at least a portion of the second active region, and includes at least two or more layers.

7. The semiconductor device of claim 1,
wherein:
the first spacer includes an inner side spacer covering a side surface of the gate structure and disposed on the second active region, and an intermediate spacer covering an external side surface of the inner side spacer,
a lower surface of the intermediate spacer is in contact with the second active region,
at least a portion of an internal side surface of the intermediate spacer is in contact with a side surface of the second active region, and
a level of the lower surface of the intermediate spacer is at a level lower than a level of a lower surface of the gate structure.

8. The semiconductor device of claim 1, wherein a thickness of the first active region is greater than a thickness of the second active region.

9. The semiconductor device of claim 1,
wherein:
the gate structure includes a gate dielectric pattern disposed on the second active region, a gate electrode on the gate dielectric pattern, and a gate capping pattern on the gate electrode,
the gate electrode includes a lower conductive pattern on the gate dielectric pattern, an intermediate conductive pattern on the lower conductive pattern, and an upper conductive pattern on the intermediate conductive pattern,
the lower conductive pattern includes at least two conductive layers, and
the upper conductive pattern includes a first upper conductive layer and a second upper conductive layer on the first upper conductive layer.

10. A semiconductor device, comprising:
a source/drain region;
a first active region disposed on one side of the source/drain region;
a second active region disposed on the first active region;
a gate structure disposed on the second active region; and
a gate spacer covering one side surface of the gate structure, and including a first spacer disposed on the second active region, and a second spacer extending along an external side surface of the first spacer and a side surface of the second active region,
wherein the source/drain region has a recessed first surface, and includes a first epitaxial pattern in contact with a side surface of the first active region, a second epitaxial pattern disposed on the recessed first surface and in contact with an external side surface of the second spacer, and a third epitaxial pattern disposed on the second epitaxial pattern and in contact with an external side surface of the second spacer.

11. The semiconductor device of claim 10, wherein the first active region includes a first region of which a width decreases in a direction away from the second active region, and a second region of which a width increases in the direction away from the second active region below the first region.

12. The semiconductor device of claim 10,
wherein:
the first active region includes single crystal silicon, and
the second active region includes single crystal silicon-germanium.

13. The semiconductor device of claim 10,
wherein:
the second epitaxial pattern and the second active region are spaced apart from one another by the second spacer, and
the first epitaxial pattern and the second active region are in contact with one another.

14. The semiconductor device of claim 10,
wherein:
the first and second epitaxial patterns include silicon-germanium compounds (SiGe),
the third epitaxial pattern includes silicon (Si), and
a concentration of germanium (Ge) in the first epitaxial pattern is lower than a concentration of germanium (Ge) in the second epitaxial pattern.

15. A semiconductor device, comprising:
a substrate;
a device isolation layer defining an active region on the substrate;
a gate structure disposed on the active region;
a source/drain region having a P-type conductivity on at least one side of the gate structure; and
a spacer covering a side surface of the gate structure,
wherein:
the spacer includes a first spacer covering the side surface of the gate structure and having a first thickness, a second spacer covering an external side surface of the first spacer and having a second thickness greater than the first thickness, and a third spacer covering an external side surface of the second spacer and having a third thickness smaller than the first thickness,
a level of a lower surface of the first spacer is at a level higher than a level of a lower surface of the third spacer, and
a level of a lower surface of the second spacer is at a level higher than a level of a lower surface of the third spacer.

16. The semiconductor device of claim 15,
wherein the active region includes:
a first active region including single crystal silicon; and
a second active region disposed on the first active region and including single crystal silicon-germanium.

17. The semiconductor device of claim 15,
wherein:
the first and third spacers include a first insulating material, and
the second spacer includes a second insulating material different from the first insulating material.

18. The semiconductor device of claim 17, wherein the first insulating material includes silicon nitride, and the second insulating material includes silicon oxide.

19. The semiconductor device of claim 15,
wherein:
the first spacer includes:
a first vertical portion in contact with the gate structure; and
a first horizontal portion extending from a lower end portion of the first vertical portion, and
an upper surface of the first horizontal portion is in contact with the second spacer.

20. The semiconductor device of claim 15, wherein a lower surface of the first spacer is at a level higher than a level of a lower surface of the second spacer.
